(19) United States
(12) Patent Application Publication
(10) Pub. No.: US 2020/0411791 A1
(43) Pub. Date: Dec. 31, 2020

(54) ELECTRODE, PEROVSKITE LIGHT-EMITTING DIODE AND PREPARING METHOD THEREOF

(71) Applicant: Shenzhen China Star Optoelectronics Semiconductor Display Technology Co., Ltd., Shenzhen, Guangdong (CN)

(72) Inventors: Miao DUAN, Shenzhen, Guangdong (CN); Chaiyu LEE, Shenzhen, Guangdong (CN); Chunche HSU, Shenzhen, Guangdong (CN); Shujhih CHEN, Shenzhen, Guangdong (CN); Pei JIANG, Shenzhen, Guangdong (CN); Bo HE, Shenzhen, Guangdong (CN); Yongming YIN, Shenzhen, Guangdong (CN); Yongwei WU, Shenzhen, Guangdong (CN)

(21) Appl. No.: 16/609,227

(22) PCT Filed: Aug. 20, 2019
(86) PCT No.: PCT/CN2019/101497

§ 371 Date: Oct. 29, 2019

(30) Foreign Application Priority Data
Jun. 26, 2019 (CN) 201910561268.5

(51) Int. Cl. H01L 51/52; H01L 51/56; H01L 51/50; H01L 51/00

(52) U.S. Cl. CPC H01L 51/5221; H01L 51/56; H01L 51/0045; H01L 51/5056; H01L 51/5072

(57) ABSTRACT

An electrode, a perovskite light-emitting diode and a preparing method thereof are provided by using a specific polymer-based surface modifier, PEIE and/or PEI, to modify carbon materials, so as to obtain an electrode with low work function, the electrode as a cathode of a perovskite light-emitting diode is more favorable for electrons injecting into the perovskite light-emitting layer.

### FIELD OF INVENTION

The present disclosure relates to the field of light-emitting device technologies, and more particularly to an electrode, a perovskite light-emitting diode, and a preparing method thereof.

### BACKGROUND OF INVENTION

The current organic-inorganic hybrid perovskite is an ABX³ type compound, A represents monovalent cation, such as CH3NH3⁺, NH2-CH=NH2+, and Cs⁺; B represents divalent cation, such as Pb2⁺, and Sn2⁺; X represents monovalent anion, such as I⁻, Br⁻, and Cl⁻. An ABX³ type compound has properties of high fluorescence quantum efficiency, narrow half-width, high color purity, adjustable optical band gap, etc., so it is very attractive in the field of light-emitting display device. In particular, with external quantum efficiencies of green and red perovskite light-emitting diodes (LEDs) breaking through 20% in succession, perovskite light-emitting diodes have attracted extensive attention from academia and industry. Therefore, research on perovskite LED is of great significant for advanced display technologies.

In general, the structure of developed perovskite LED device is indium tin oxide layer/hole transport layer/perovskite light-emitting layer/electron transport layer/metal electrode. Indium tin oxide layer is an anode, metal electrode is a cathode. Due to the high prices of metal electrodes and high requirement for manufacturing the equipment, when using a low-cost, highly conductive carbon material as a cathode, the work function of carbon materials is higher than metals, and makes it difficult to inject electrons into a perovskite light-emitting layer.

Therefore, it is necessary to provide a technical solution to solve the problem of electrons having difficulties to inject into a perovskite light-emitting layer due to the higher work function of cathodes made from a carbon material.

### SUMMARY OF INVENTION

An object of the present disclosure is to provide an electrode, a perovskite light-emitting diode and a preparing method thereof, to solve the problem of electrons having difficulties to inject into a perovskite light-emitting layer due to the higher work function of cathodes made from a carbon material.

To achieve the above object, an embodiment of the present disclosure provides:

an electrode, preparing materials for the electrode comprising a carbon material and a surface modifier, and the surface modifier including a polymer having a following structural formula (1) and/or a structural formula (2),

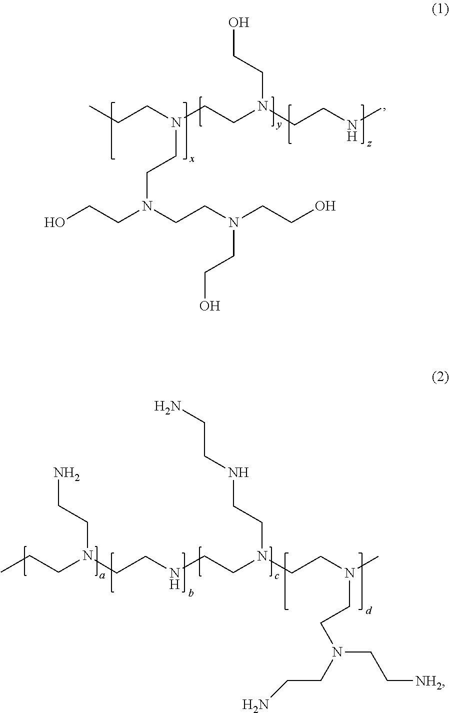

wherein x, y, and z are integers greater than or equal to 1; a, b, c, and d are integers greater than or equal to 1.

In the above electrode, the mass ratio of the surface modifier to the carbon material ranges from 0.01:100 to 10:100.

In the above electrode, the mass ratio of the surface modifier to the carbon material ranges from 0.1:100 to 2:100.

In the above electrode, the carbon material is at least one selected from one group of graphene, graphite, carbon nanotubes and carbon black.

In the above electrode, the carbon material is graphite.

An embodiment of the present disclosure further provides a perovskite light-emitting diode. The perovskite light-emitting diode comprises a cathode, preparing materials for the cathode comprising a carbon material and a surface modifier, and the surface modifier including a polymer having a following structural formula (1) and/or a structural formula (2),

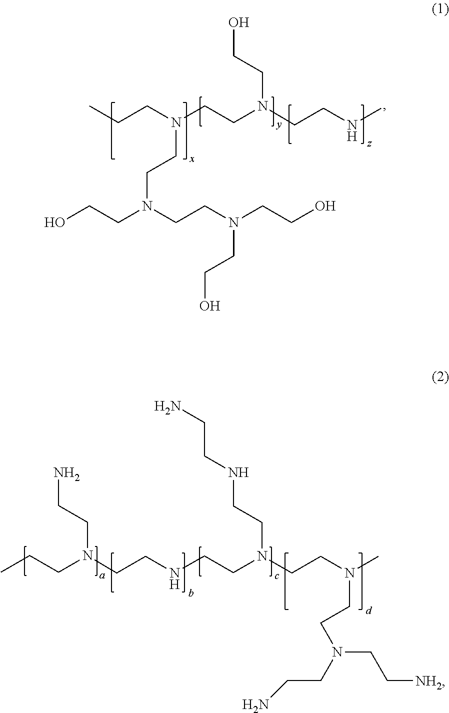

wherein x, y, and z are integers greater than or equal to 1; a, b, c, and d are integers greater than or equal to 1.

In the above perovskite light-emitting diode, the mass ratio of the surface modifier to the carbon material ranges from 0.01:100 to 10:100.

In the above perovskite light-emitting diode, the mass ratio of the surface modifier to the carbon material ranges from 0.1:100 to 2:100.

In the above perovskite light-emitting diode, the carbon material is at least one selected from one group of graphene, graphite, carbon nanotubes and carbon black.

In the above perovskite light-emitting diode, the carbon material is graphite.

An embodiment of the present disclosure further provides a preparing method of a perovskite light-emitting diode. The preparing method of a perovskite light-emitting diode comprises following steps:

providing a substrate formed with an anode;

forming a hole transport layer on one surface of the anode;

forming a perovskite light-emitting layer on a surface of the hole transport layer away from the anode;

forming an electron transport layer on a surface of the perovskite light-emitting layer away from the hole transport layer;

coating a slurry mixture of a surface modifier and a carbon material on a surface of the electron transport layer away from the perovskite light-emitting layer, and removing solvents from the carbon material slurry at a default temperature to form a cathode;

wherein the carbon material slurry comprises a carbon material and a solvent, and the surface modifier includes a polymer having a following structural formula (1) and/or a structural formula (2),

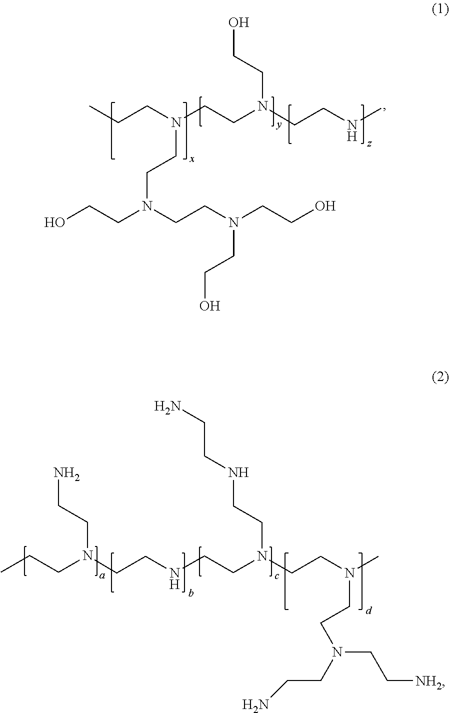

wherein x, y, and z are integers greater than or equal to 1; a, b, c, and d are integers greater than or equal to 1.

Beneficial effect: the present disclosure provides an electrode, a perovskite light-emitting diode and a preparing method thereof by using a specific polymer-based surface modifier, PEIE and/or PEI, to modify carbon materials, so as to obtain an electrode with low work function, the electrode as a cathode of a perovskite light-emitting diode is more favorable for electrons injecting into a perovskite light-emitting layer.

### DESCRIPTION OF DRAWINGS

FIG. 1 is a schematic structural diagram of a perovskite light-emitting diode of the present disclosure.

### DETAILED DESCRIPTION OF PREFERRED EMBODIMENTS

The embodiments of the present disclosure are described in detail hereinafter. Examples of the described embodiments are given in the accompanying drawings. Obviously, the description of embodiments is only part of the embodiments of the present disclosure, from which embodiments those skilled in the art can derive further embodiments without making any inventive efforts.

The description of the surface modifier is as following:

ethoxylated polyethyleneimine (PEIE), having a structural formula of formula (1) as following,

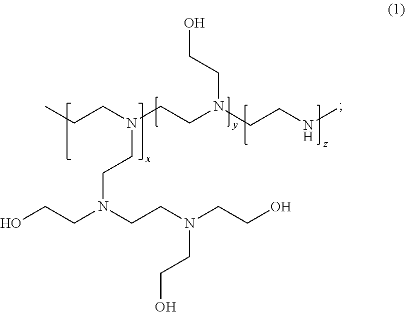

wherein x, y, and z are integers greater than or equal to 1.

In the following embodiments, PEIE is a 80% purity PEIE (M_{w}=110000) aqueous solution bought from Sigma-Aldrich Company, and the mass ratio of PEIE is 37%.

Branched polyethyleneimine (PEI), having a structural formula of formula (2) as following,

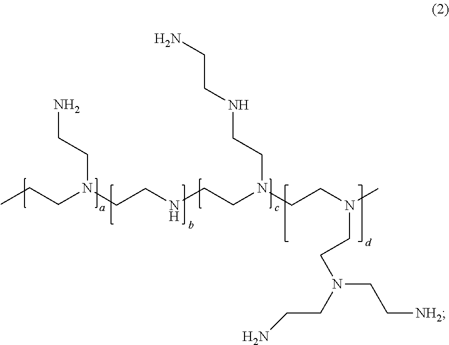

wherein a, b, c, and d are integers greater than or equal to 1.

In the following embodiments, PEI is bought from Sigma-Aldrich Company, and the number average molecular weight of PEIE is about 25000.

Use surface modifiers and carbon materials to prepare electrodes of following embodiment 1 to embodiment 7, use graphene and graphite to prepare electrodes of comparative embodiment 1 and comparative embodiment 2, and obtain work functions and sheet resistances of embodiment 1 to embodiment 7, comparative embodiment 1 and comparative embodiment 2 under the same test condition, as shown in Table 1 specifically:

TABLE 1
Compositions, work functions and sheet resistances of embodiment 1 to
embodiment 7, comparative embodiment 1 and comparative embodiment 2.

| | Embodi- | Embodi- | Embodi- | Embodi- | Embodi- | Embodi- | Embodi- | Comparative | Comparative |
|---|---|---|---|---|---|---|---|---|---|
| | ment 1 | ment 2 | ment 3 | ment 4 | ment 5 | ment 6 | ment 7 | embodiment 1 | embodiment 2 |
| composi- | PEIE/ | PEIE/ | PEIE/ | PEIE/ | PEIE/ | PEIE/ | PEI/ | graphite = | graphene = |
| tion | graphite = | graphite = | graphite = | graphite = | graphite = | graphene = | graphite = | 101 g | 101 g |
| | 0.01 g/100 g | 0.1 g/100 g | 1 g/100 g | 1.8 g/100 g | 9 g/100 g | 1 g/100 g | 1 g/100 g | | |
| Work | −4.48 | −4.3 | −4.1 | −3.8 | −3.5 | −4.3 | −4 | −4.5 | −4.6 |
| function | | | | | | | | | |
| (eV) | | | | | | | | | |
| Sheet | 3 | 8 | 15 | 25 | 50 | 25 | 16 | 1 | 6 |
| resistance | | | | | | | | | |
| (ohm/sq) | | | | | | | | | |

It can be known from table 1, the work functions of electrodes made from graphite and graphene are individual −4.5 eV and −4.6 eV. The sheet resistance of 101 g graphite is 1 ohm/sq, and the sheet resistance of 101 g graphene is 6 ohm/sq, so the conductivity of graphite is better than graphene under the same condition.

When using graphite and PEIE as preparing materials for the electrode, with the mass of graphite unchanged and the mass of PEIE increased, the absolute value of the work function of the electrode is gradually decreased, and the sheet resistance of the electrode is gradually increased. When the mass of PEIE is 0.01 g, the work function of the electrode is −4.48 eV, which is not significantly decreased comparing to the work function of graphite electrode; however, when the mass of PEIE is 9 g, the work function of the electrode is −4.3, and the sheet resistance is 50 ohm/sq. Although the work function of the electrode is smaller, the conductivity of the electrode is significantly decreased comparing to graphite electrode. When the mass ratio of PEIE to graphite ranges from 0.1:100 to 2:100, a balance between the work function and the conductivity can be achieved, and is more favorable for applying the electrode to light-emitting diodes. In addition, it can be known from embodiment 6 and comparative embodiment 2, When using graphene and PEIE as preparing materials for the electrode, the work function of the electrode made from graphene and PEIE is increased by 0.3 eV comparing to the electrode made from graphene; that is, adding PEIE to graphene causes the work function of graphene to decrease. It can be known from embodiment 7, using PEI as a surface modifier to modify graphite can also obtain the electrode with low work function.

It can be known from above disclosure, the more surface modifier (PEI or PEIE) contained in the carbon materials, the more significant increase in the work function of the electrode, and the smaller the absolute value of the work function of the electrode. The main reason is that the surface modifier adheres to the surface of the carbon material, and changes the state of electronic clouds on the surface of the carbon material, thereby decreasing the work function of the carbon material. However, adding too much surface modifier to the carbon material will cause the conductivity of the carbon material to decrease significantly, which is not favorable to the conductivity of the electrode.

Besides, from comparative embodiment 1 and embodiment 3, and comparative embodiment 2 and embodiment 6, the difference between the work function of the electrode made from 1 g PEIE and 100 g graphite and the work function of the electrode made from 101 g graphite is 0.4 eV, and the difference between the work function of the electrode made from 1 g PEIE and 100 g graphene and the work function of the electrode made from 101 g graphene is 0.3 eV. It can be known, comparing to graphene, the work function of graphite drops more significantly by PEIE. In addition, comparing to graphene, the sheet resistance of graphite increases less by PEIE.

### Embodiment 8

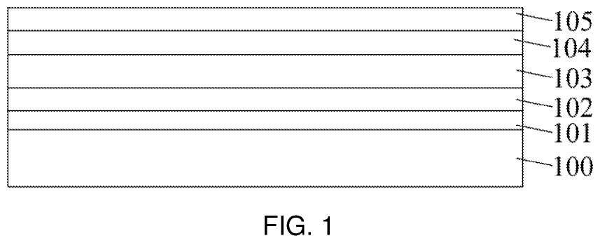

As shown in FIG. 1, it is a schematic structural diagram of a perovskite light-emitting diode of the present disclosure. The perovskite light-emitting diode comprises a substrate 100, an anode 101, a hole transport layer 102, a perovskite light-emitting layer 103, an electron transport layer 104, and a cathode 105. The anode 101 is formed on one surface of the substrate 100, the hole transport layer 102 is formed on the surface of the anode 101 away from the substrate 100, the perovskite light-emitting layer 103 is formed on the surface of the hole transport layer 102 away from the anode 101, the electron transport layer 104 is formed on the surface of the perovskite light-emitting layer 103 away from the hole transport layer 102, the cathode 105 is formed on the surface of the electron transport layer 104 away from the perovskite light-emitting layer 103. The composition of the perovskite light-emitting diode is as shown in table 2 below:

| | composition |
|---|---|
| anode | Indium tin oxide (ITO) |
| hole transport | Poly-3,4-Ethylenedioxythiophene (PEDOT)/ |
| layer | Polystyrene sulfonate (PSS) |
| perovskite | CH₃NH₃PbBr₃ |
| light-emitting layer | |
| electron transport | 1,3,5-tris(1-phenyl-1H-benzimidazol-2-yl) benzene |
| layer | (TBPI) |
| cathode | Carbon material and surface modifier |

Wherein the work function of the anode 101 is −4.8 eV, the work function of the hole transport layer 102 is −5.2 eV, the conduction band level of the perovskite light-emitting layer 103 is −3.4 eV, the valent band level of the perovskite light-emitting layer 103 is −5.6 eV, the conduction band level of the electron transport layer 104 is −2.7 eV, and the valent band level of the electron transport layer 104 is −6.2 eV.

Electrons flow out from the cathode 105. Since the thickness of the electron transport layer 104 is relatively thin (about 2 nm), the energy level matching effect is small, so the conduction band level of the perovskite light-emitting layer 103 is mainly considered. From embodiment 1 to 7, the work function of the electrode is −4.48 eV to −3.5 eV. That is, the work function of the electrode is smaller than the conduction band level of the perovskite light-emitting layer 103, so when using the electrode as a cathode, the difference of energy level between the cathode 105 and the perovskite light-emitting layer 103 is smaller than the difference of energy level between the carbon material cathode and the perovskite light-emitting layer 103. It is because of using the surface modifier (PEIE and/or PEI) to modify the carbon material, making the work function of the cathode made from the two components more match the energy level of the perovskite light-emitting layer, and more favorable for electrons injecting into the perovskite light-emitting layer.

### Embodiment 9

This embodiment is the preparing method of the perovskite light-emitting diode as shown in embodiment 8, comprising the following steps:

S11: providing a substrate 100 formed with an anode 101.

Specifically, providing a glass substrate formed with an indium tin oxide layer.

S12: forming a hole transport layer 102 on one surface of the anode 101.

Specifically, using ultraviolet light and ozone treating the glass substrate formed with an indium tin oxide layer, spin-coating a PEDOT:PSS aqueous solution on the indium tin oxide layer at 3000 r/min for 1 minute, and moving the glass substrate coated with the PEDOT:PSS aqueous solution to a 150° C. hot plate for 10 minutes annealing treatment to form a hole transport layer. The PEDOT:PSS aqueous solution is purchased.

S13: forming a perovskite light-emitting layer 103 on the surface of the hole transport layer 102 away from the anode 101.

Specifically, adding a perovskite precursor solution to the surface of the hole transport layer away from the anode 101, spin-coating at 4000 r/min for 30 seconds, adding 250 μL of anti-solvent, chlorobenzene, about 10 seconds since the spin-coating, and placing on a 90° C. hot plate for annealing treatment after the spin-coating to obtain the perovskite light-emitting layer. Wherein the perovskite precursor solution mainly contains CH₃NH₃PbBr₃.

S14: forming an electron transport layer 104 on the surface of the perovskite light-emitting layer 103 away from the hole transport layer 102.

Specifically, placing the substrate 100 formed with the perovskite light-emitting layer 103 in a vacuum coater, and depositing TBPI on the surface of the perovskite light-emitting layer 103 away from the hole transport layer 102 to form an electron transport layer.

S15: coating a slurry mixture of a surface modifier and a carbon material on the surface of the electron transport layer 104 away from the perovskite light-emitting layer 103, and removing solvents from the carbon material slurry at a default temperature to form a cathode 105, the surface modifier including a polymer having the following structural formula (1) and/or structural formula (2),

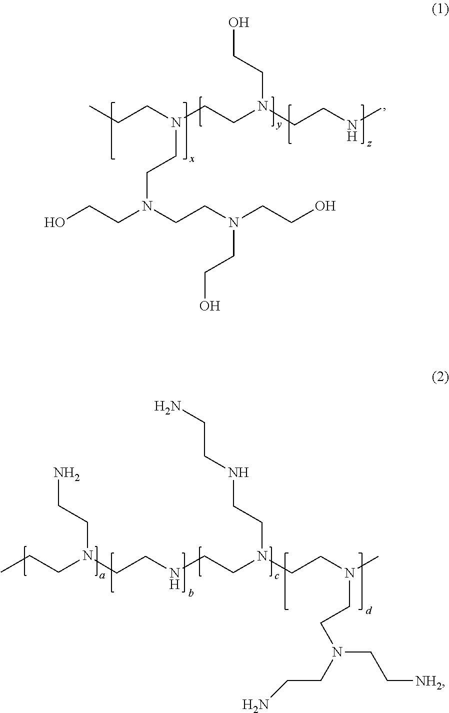

wherein x, y, and z are integers greater than or equal to 1; a, b, c, and d are integers greater than or equal to 1.

Specifically, mixing the surface modifier and the carbon material slurry, ball mill grinding to obtain a mixture of the surface modifier and the carbon material, coating the mixture of the surface modifier and the carbon material on the surface of the electron transport layer away from the perovskite light-emitting layer by a simple blade coating process, and annealing at a default temperature to remove the solvents from the carbon material slurry to form a cathode.

The carbon material slurry is commercial grade, and mainly contain a carbon material and a solvent for dissolving the carbon material. The carbon material is a micron carbon material or a nano carbon material. The carbon material is at least one selected from a group consisting of graphene, graphite, carbon nanotubes and carbon black. Specifically, the carbon material is graphite.

In this embodiment, the mass ratio of the surface modifier to the carbon material ranges from 0.01:100 to 10:100. Further, the mass ratio of the surface modifier to the carbon material ranges from 0.1:100 to 2:100.

The preparing method of the perovskite light-emitting diode in this embodiment using a specific polymer-based surface modifier, PEIE and/or PEI, to modify the carbon material that obtain a cathode with low work function, and the cathode is more favorable for electrons injecting into the perovskite light-emitting layer.

The description of the above embodiments is only for helping to understand the technical solution of the disclosure and its core ideas and it is understood that many changes and modifications to the described embodiment can be carried out without departing from the scope and the spirit of the disclosure that is intended to be limited only by the appended claims.

1. electrode, preparing materials for the electrode comprising a carbon material and a surface modifier, and the surface modifier including a polymer having a following structural formula (1) and/or a structural formula (2), 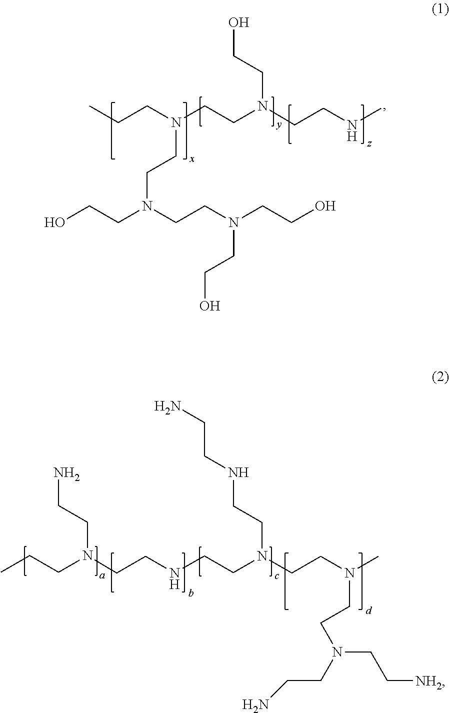
wherein x, y, and z are integers greater than or equal to 1; a, b, c, and d are integers greater than or equal to 1.

2. The electrode according to claim 1, the mass ratio of the surface modifier to the carbon material ranges from 0.01:100 to 10:100.

3. The electrode according to claim 1, the mass ratio of the surface modifier to the carbon material ranges from 0.1:100 to 2:100.

4. The electrode according to claim 1, the carbon material is at least one selected from a group consisting of graphene, graphite, carbon nanotubes and carbon black.

5. The electrode according to claim 1, the carbon material is graphite.

6. A perovskite light-emitting diode, the perovskite light-emitting diode comprising a cathode, preparing materials for the cathode comprising a carbon material and a surface modifier, and the surface modifier including a polymer having a following structural formula (1) and/or a structural formula (2), 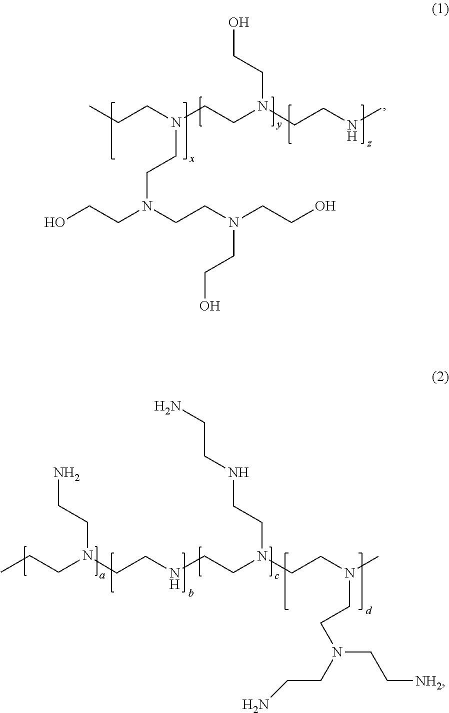
wherein x, y, and z are integers greater than or equal to 1; a, b, c, and d are integers greater than or equal to 1.

7. The perovskite light-emitting diode according to claim 6, the mass ratio of the surface modifier to the carbon material ranges from 0.01:100 to 10:100.

8. The perovskite light-emitting diode according to claim 6, the mass ratio of the surface modifier to the carbon material ranges from 0.1:100 to 2:100.

9. The perovskite light-emitting diode according to claim 6, the carbon material is at least one selected from a group consisting of graphene, graphite, carbon nanotubes and carbon black.

10. The perovskite light-emitting diode according to claim 6, the carbon material is graphite.

11. A preparing method of perovskite light-emitting diode, the preparing method of perovskite light-emitting diode comprising the following steps:
providing a substrate formed with an anode;
forming a hole transport layer on one surface of the anode;
forming a perovskite light-emitting layer on the surface of the hole transport layer away from the anode;
forming an electron transport layer on the surface of the perovskite light-emitting layer away from the hole transport layer;
coating a slurry mixture of a surface modifier and a carbon material on the surface of the electron transport layer away from the perovskite light-emitting layer, and removing solvents from the carbon material slurry at a default temperature to form a cathode; the surface modifier including a polymer having a following structural formula (1) and/or a structural formula (2), 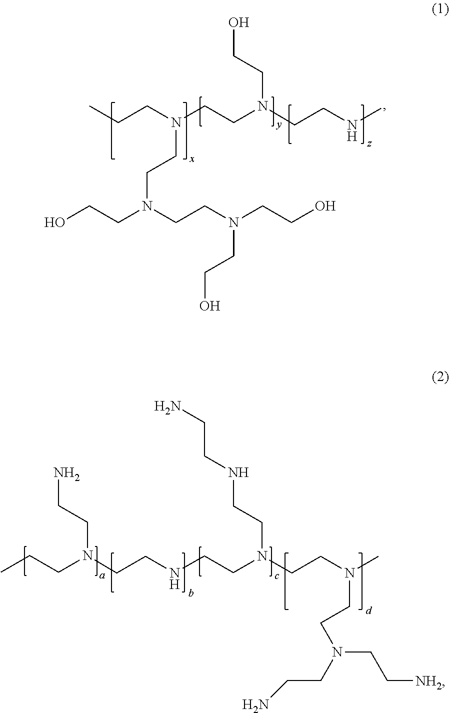
wherein x, y, and z are integers greater than or equal to 1; a, b, c, and d are integers greater than or equal to 1.
